(19) United States
(12) Patent Application Publication
(10) Pub. No.: US 2025/0374468 A1
(43) Pub. Date: Dec. 4, 2025

(54) REMOTE RELEASE MODULE AND CIRCUIT BOARD DEVICE

(71) Applicant: GIGA-BYTE TECHNOLOGY CO.,LTD., New Taipei City (TW)

(72) Inventors: Chih-Ming Lai, New Taipei City (TW); Yung-Shun Kao, New Taipei City (TW); Hui-Shan Chou, New Taipei City (TW)

(73) Assignee: GIGA-BYTE TECHNOLOGY CO.,LTD., New Taipei City (TW)

(21) Appl. No.: 19/073,015

(22) Filed: Mar. 7, 2025

(30) Foreign Application Priority Data
May 30, 2024 (TW) 113119923

(51) Int. Cl. H05K 7/14

(52) U.S. Cl. CPC H05K 7/1402; H05K 7/1439

(57) ABSTRACT

A remote release module includes a button, a moving member, a rotating shaft and at least one hook. The moving member is linked to the button and includes a first driving portion. The rotating shaft includes a second driving portion protruding from a peripheral side and at least a third driving portion, and the second driving portion is linked to the first driving portion. The at least one hook is disposed beside the at least one third driving portion. When the button is pressed, the moving member is driven, and the first driving portion drives the second driving portion to rotate the rotating shaft, and then the at least one third driving portion drives the at least one hook to retract.

### CROSS-REFERENCE TO RELATED APPLICATION

This application claims the priority benefit of TW application serial no. 113119923, filed on May 30, 2024. The entirety of the above-mentioned patent application is hereby incorporated by reference herein and made a part of this specification.

### BACKGROUND

### Technical Field

The present invention relates to a remote release module and a circuit board device.

### Related Art

Currently, when an expansion card is inserted into a motherboard, it may be released by pressing a release device. With the advancement of technology, AI and high-end audio-visual products have a demand for using multiple expansion cards simultaneously. Due to the large volume of the expansion card assembly composed of the expansion card and the assembled heat dissipation structure, when multiple expansion card assemblies are inserted into the motherboard simultaneously, the release device used to release the expansion card may be shielded by another expansion card assembly and cannot be pressed.

Therefore, to remove the expansion card assembly located on the inner side which is away from the edge of the motherboard, it is necessary to remove the outermost expansion card assembly to expose the release device for releasing the second expansion card assembly near the outer side which is close to the edge of the motherboard, so that the user can press this release device to release the second expansion card assembly. If the innermost expansion card assembly needs to be removed, all expansion card assemblies outside the innermost expansion card assembly must be removed before the innermost expansion card assembly can be taken out, which is quite inconvenient for the user.

### SUMMARY

The present invention provides a remote release module, which may drive the hook from a remote location to complete the release.

The present invention provides a circuit board device, including the aforementioned remote release module.

A remote release module of the present invention includes a button, a moving member, a rotating shaft, and at least one hook. The moving member is linked to the button and includes a first driving portion. The rotating shaft includes a second driving portion and at least one third driving portion protruding from a peripheral side, with the second driving portion linked to the first driving portion. At least one hook is disposed next to at least one third driving portion. When the button is pressed, it drives the moving member, the first driving portion drives the second driving portion, causing the rotating shaft to rotate, thereby causing at least one third driving portion to drive at least one hook to retract.

In an embodiment of the present invention, the aforementioned remote release module further includes a first base, wherein the rotating shaft is pivotally disposed on the first base, and the first base includes at least one first track, along which at least one hook moves.

In an embodiment of the present invention, the aforementioned first base includes at least one second track, communicating with at least one first track, along which at least one hook moves.

In an embodiment of the present invention, the aforementioned remote release module further includes at least one first elastic member, disposed between the first base and at least one hook.

In an embodiment of the present invention, the aforementioned rotating shaft includes an end surface and a blocking portion protruding from the peripheral side, wherein the projection of the blocking portion projected onto the end surface is located between the projection of the second driving portion projected onto the end surface and the projection of at least one third driving portion projected onto the end surface.

In an embodiment of the present invention, the aforementioned at least one third driving portion includes multiple third driving portions, the third driving portions extend in parallel from the peripheral side, at least one hook includes multiple hooks, the hooks are respectively disposed next to the third driving portions. When the button is pressed, it drives the moving member, the first driving portion drives the second driving portion, causing the rotating shaft to rotate, thereby causing the third driving portions to drive the hooks to retract simultaneously.

In an embodiment of the present invention, the aforementioned remote release module further includes a second base, wherein the button may be pressably disposed at the second base, the second base includes a third track, and the moving member includes a protrusion, slidably disposed in the third track.

In an embodiment of the present invention, the aforementioned second base includes a first section and a second section connected in a bent manner, the button may be pressably disposed at the first section, and the third track is located at the second section.

In an embodiment of the present invention, the aforementioned button includes a first inclined surface, and the moving member includes a second inclined surface that leans on the first inclined surface.

In an embodiment of the present invention, the aforementioned button is a push-push button. When the button is pressed, one end of a second elastic member slides along a groove structure on the wall surface of the button, so that the button stays at a lower position or an upper position.

A circuit board device of the present invention includes a circuit board body, at least one connector socket, and the aforementioned remote release module. The connector socket is disposed on the circuit board body. At least one hook is driven by the button to retract away from at least one connector socket.

Based on the above, in the circuit board device and remote release module of the present invention, the button is linked with the moving member, and the second driving portion of the rotating shaft is linked to the first driving portion. The at least one hook is disposed beside to at least one third driving portion of the rotating shaft. When the button is pressed, it drives the moving member, the first driving portion drives the second driving portion, causing the rotating shaft to rotate, thereby causing at least one third driving portion to drive at least one hook to retract. Since the button may be disposed at a remote location and will not be shielded, it can drive the hook to retract from a remote location to complete the release of the expansion card. Moreover, the quantity of the third driving portions and hooks may be one or more, therefore, the button can simultaneously drive one or more hooks, thus enhancing convenience.

### BRIEF DESCRIPTION OF THE DRAWINGS

FIG. 1 is a perspective view illustrating a circuit board device according to an embodiment of the present invention.

FIG. 2A is a side view illustrating the circuit board device of FIG. 1 before the button is pressed.

FIG. 2B is a partially enlarged view of FIG. 2A.

FIG. 2C is a perspective view of FIG. 2B.

FIG. 3A is a side view illustrating the circuit board device of FIG. 1 after the button is pressed.

FIG. 3B is a partially enlarged view of FIG. 3A.

FIG. 3C is a perspective view of FIG. 3B.

FIG. 4 is a perspective view of the remote release module of FIG. 1 before the button is pressed.

FIG. 5 is a perspective view of the remote release module of FIG. 1 after the button is pressed.

FIG. 6 is a schematic view of the rotating shaft of FIG. 4.

FIG. 7 is a partially enlarged view of FIG. 5.

FIG. 8 and FIG. 9 are schematic views of different cross-sections of the remote release module of FIG. 1.

FIG. 10 is a schematic view of the bottom surface of the second base of the remote release module of FIG. 1.

FIG. 11 is a cross-sectional view of the button and the moving member of the remote release module of FIG. 1.

FIG. 12 is a partially schematic view of the button, the second elastic member, and the moving part of the remote release module of FIG. 1.

### DESCRIPTION OF THE EMBODIMENTS

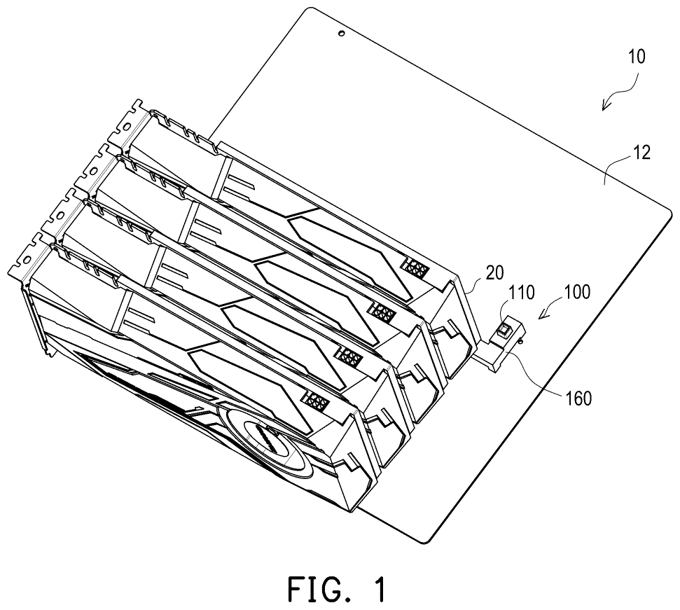

FIG. 1 is a perspective view of a circuit board device according to an embodiment of the present invention. Referring to FIG. 1, the circuit board device 10 of this embodiment includes a circuit board body 12, at least one connector socket 14, and a remote release module 100. In this embodiment, the quantity of connector sockets 14 is multiple, and the connector sockets 14 are arranged in parallel on the circuit board body 12 for insertion of expansion cards 20.

In this embodiment, the remote release module 100 may release all expansion cards 20 inserted into the connector sockets 14 at once. The detailed structure of the remote release module 100 will be explained below.

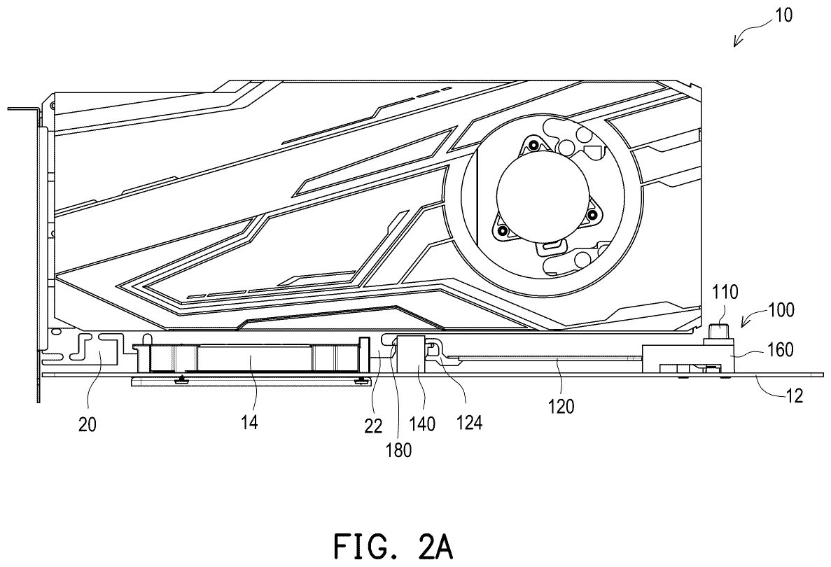

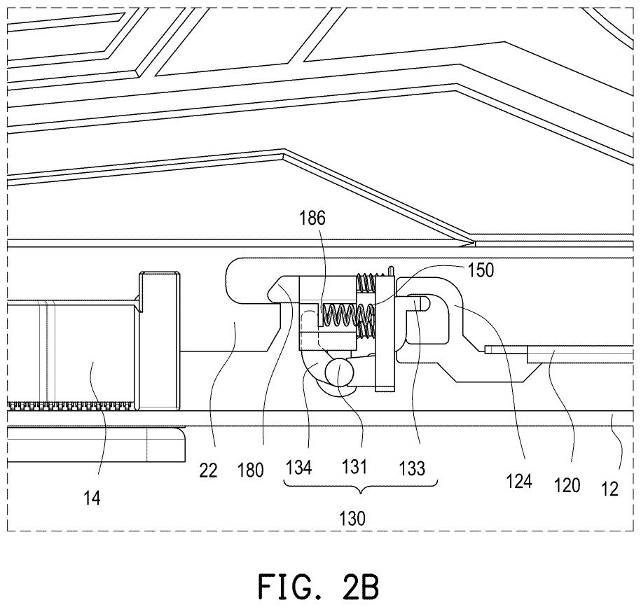

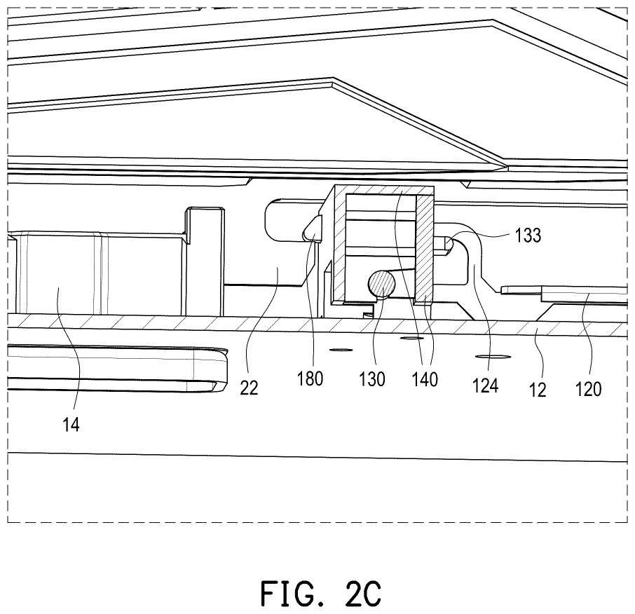

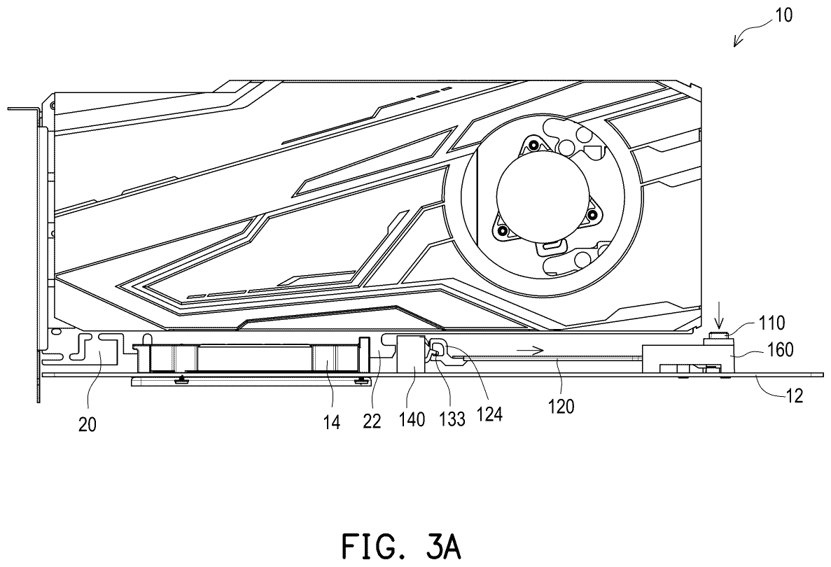

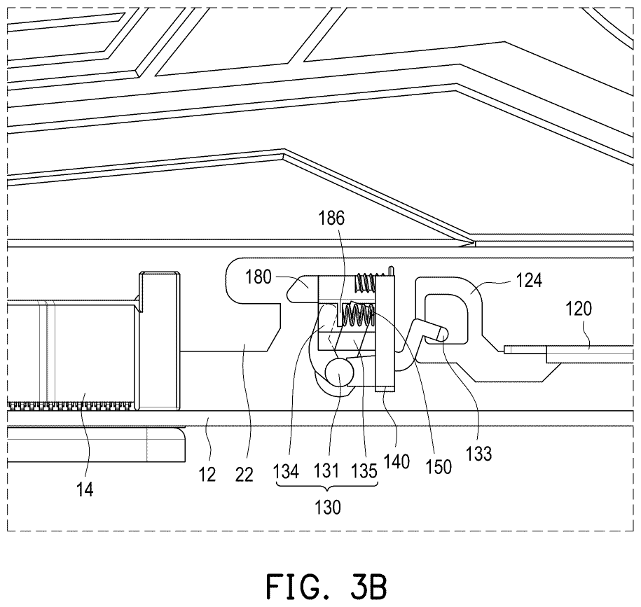

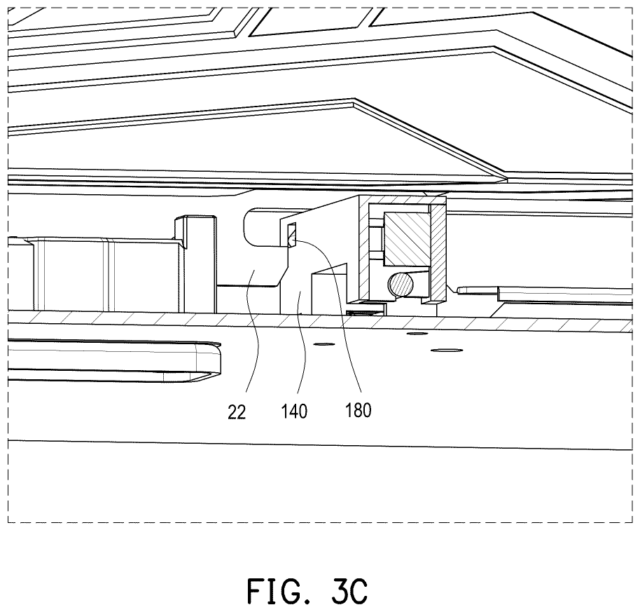

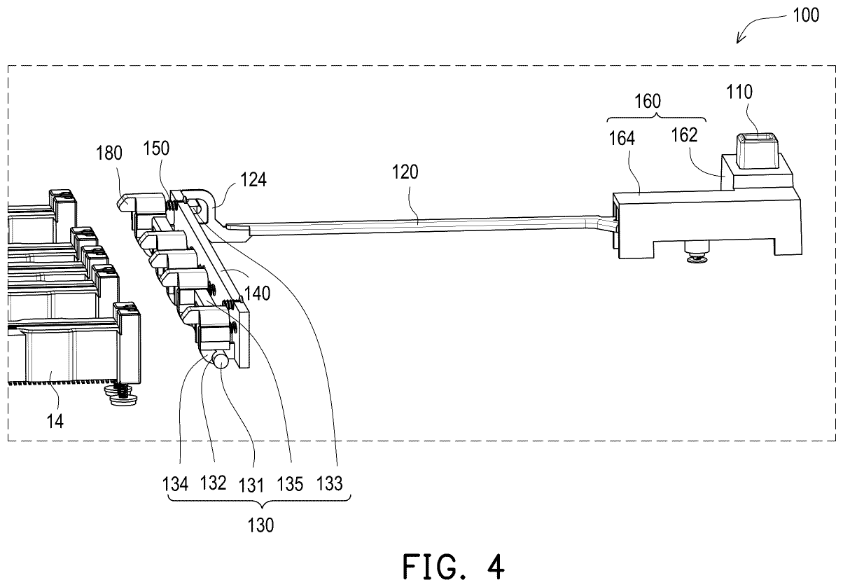

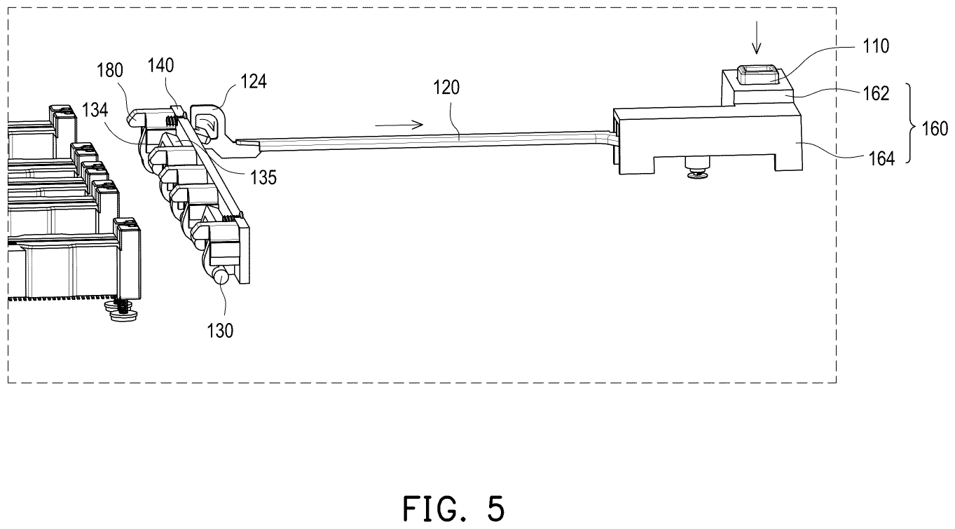

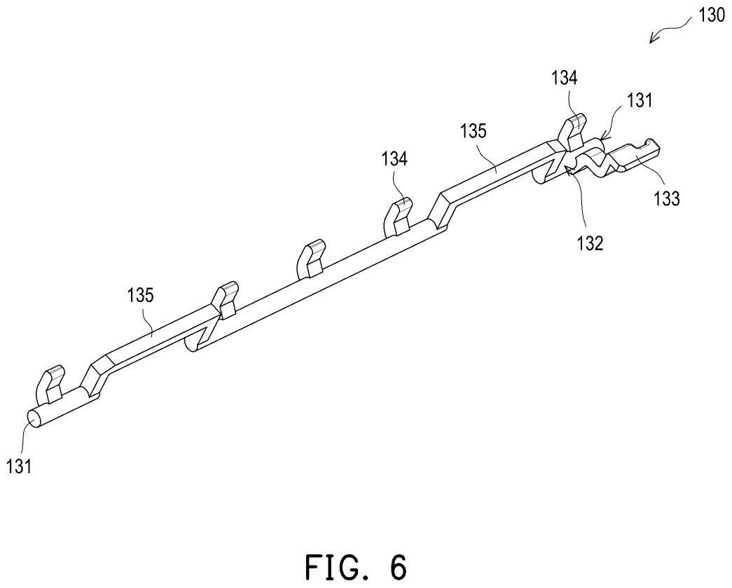

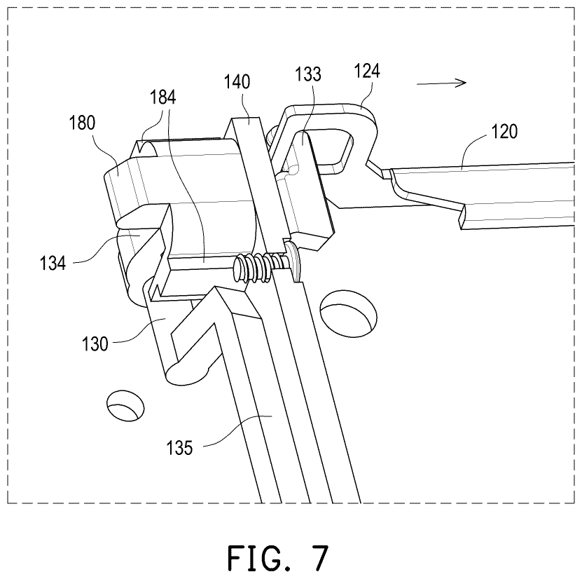

FIG. 2A is a side view of the circuit board device of FIG. 1 before pressing the button. FIG. 2B is a partially enlarged view of FIG. 2A. FIG. 2C is a perspective view of FIG. 2B. FIG. 3A is a side view of the circuit board device of FIG. 1 after pressing the button. FIG. 3B is a partially enlarged view of FIG. 3A. FIG. 3C is a perspective view of FIG. 3B. FIG. 4 is a perspective view of the remote release module of FIG. 1 before pressing the button. FIG. 5 is a perspective view of the remote release module of FIG. 1 after pressing the button. FIG. 6 is a schematic view of the rotating shaft of FIG. 4. FIG. 7 is a partially enlarged view of FIG. 5. It should be noted that a portion of the first base 140 is hidden in FIG. 2B, FIG. 3B, FIG. 4, FIG. 5, and FIG. 7.

Referring to FIG. 2A to FIG. 7, the remote release module 100 of this embodiment includes a button 110, a moving member 120, a rotating shaft 130, and at least one hook 180. The button 110 may be disposed at a position of the circuit board body 12 near the edge of the circuit board body 12, or at a position of the circuit board body 12 away from the expansion cards 20 (FIG. 1), to avoid being shielded by the expansion cards 20. As shown in FIG. 5, the moving member 120 is linked with the button 110, and includes a first driving portion 124 away from the button 110.

As shown in FIG. 2C, the remote release module 100 further includes a first base 140 fixed on the circuit board body 12, and the rotating shaft 130 pivotally disposed on the first base 140. As shown in FIG. 6, the rotating shaft 130 includes two end surfaces 131 and a second driving portion 133, at least one third driving portion 134, and at least one blocking portion 135 protruding from a peripheral side 132. In this embodiment, the at least one third driving portion 134 includes multiple third driving portions 134, the third driving portions 134 extends in parallel from the peripheral side 132.

Moreover, as seen in FIG. 6, the quantity of blocking portions 135 is multiple (for example, two), the two blocking portions 135 near the two end surfaces 131, but the quantity and position of the blocking portions 135 are not limited thereto. The second driving portion 133 and the rightmost third driving portion 134 are located on both sides of the rightmost blocking portion 135. In other words, the projection of the blocking portion 135 projected onto the end surface 131 (for example, the right end surface 131 in FIG. 6) is between the projection of the second driving portion 133 projected onto the end surface 131 and the projection of the third driving portion 134 projected onto the end surface 131.

As shown in FIG. 7, the second driving portion 133 is linked with the first driving portion 124. The first driving portion 124 drives the second driving portion 133, causing the rotating shaft 130 to rotate. The relative position design between the blocking portion 135 and the third driving portion 134 may allow the blocking portion 135 to contact the first base 140 before the third driving portion 134 when the rotating shaft 130 rotates, thus achieving the function of being limited by the first base 140.

In addition, as shown in FIG. 4, the at least one hook 180 is disposed next to at least one third driving portion 134. The at least one hook 180 includes multiple hooks 180, the hooks 180 are respectively disposed next to the third driving portions 134.

In this embodiment, the quantity of each of the connector sockets 14, hooks 180, and third driving portions 134 is, for example, five, but the quantity of the connector sockets 14, hooks 180, and third driving portions 134 is not limited thereto. In an unillustrated embodiment, the quantity of hooks 180 and third driving portions 134 may also be only one or other quantities.

As shown in FIG. 3A, when pressing the button 110, it drives the moving member 120 to move right. As shown in FIG. 3B, the first driving portion 124 of the moving member 120 drives the second driving portion 133 of the rotating shaft 130, causing the rotating shaft 130 to rotate relative to the first base 140 (only the part used to limit the blocking portion 135 is illustrated), thereby causing the third driving portion 134 of the rotating shaft 130 to rotate.

In this embodiment, the hook 180 includes a push-receiving portion 186, the third driving portion 134 is located next to the push-receiving portion 186, and may drive the push-receiving portion 186 to move, causing the hook 180 to retract. Therefore, the hook 180 moves away from above the fixing hook 22 of the expansion card 20, allowing the expansion card 20 to be pulled up from the connector socket 14.

In this embodiment, since the rotating shaft 130 may drive the third driving portions 134 to rotate together, the third driving portions 134 drive the hooks 180 to retract together. Therefore, when the user presses the button 110, it may simultaneously release the expansion cards 20 that are restricted by the hooks 180, without the need to remove the expansion cards 20 closer to the button 110 first before removing the expansion cards 20 away from the button 110. The expansion card 20 which is desired to be removed can be directly removed, effectively improving convenience.

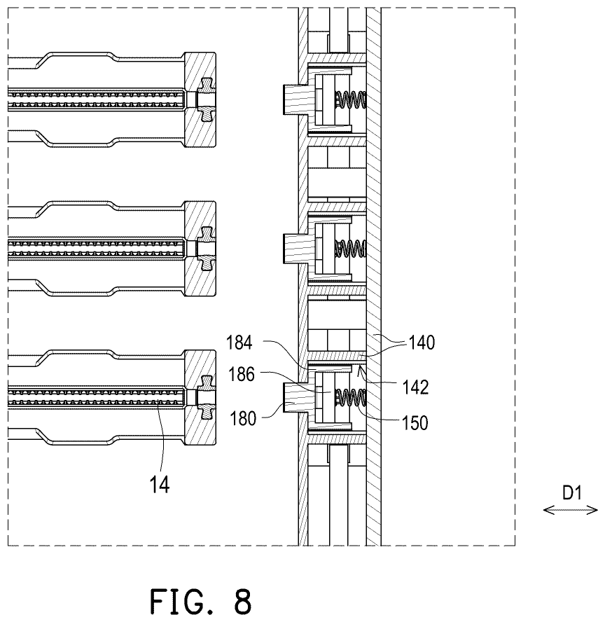

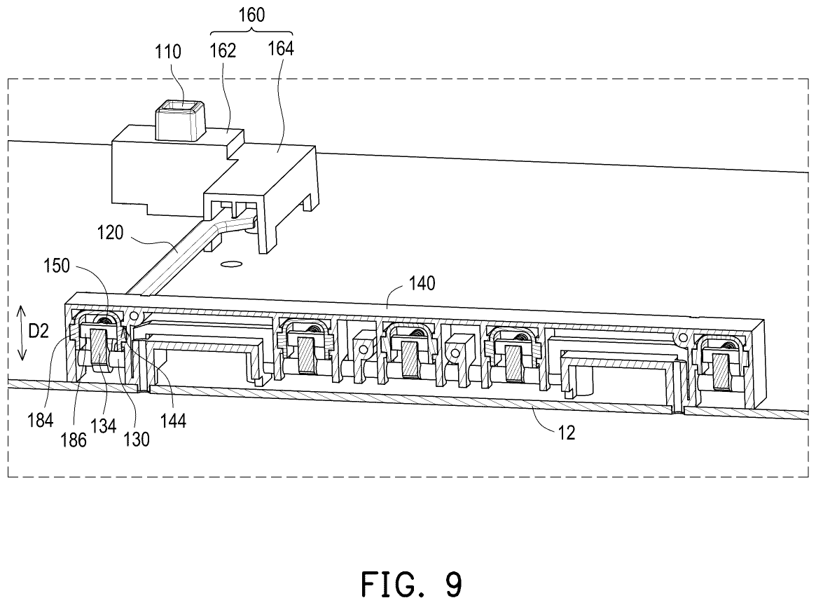

FIG. 8 and FIG. 9 are schematic views of different cross-sections of the remote release module of FIG. 1. It should be noted that FIG. 8 shows a perspective of horizontally cross-sectioning the first base 140 parallel to the plane of the circuit board body 12, while FIG. 9 shows a perspective of vertically cross-sectioning the first base 140 perpendicular to the plane of the circuit board body 12.

Please refer to FIG. 8 first. In this embodiment, the first base 140 includes at least one first track 142, the quantity of first tracks 142 may correspond to the quantity of hooks 180. The hook 180 moves stably along the first track 142 in a first direction D1, without swaying left and right (up and down direction in FIG. 8) during movement.

Please refer to FIG. 9. The first base 140 includes at least one second track 144, communicating with at least one first track 142. In this embodiment, two sliders 184 protruding left and right are disposed on both sides of each hook 180, and the quantity of second tracks 144 may correspond to the quantity of sliders 184. The sliders 184 of the hook 180 move along the second track 144, so that when the hook 180 moves along the first direction D1 (FIG. 8), it does not sway up and down in the second direction D2. Therefore, the hook 180 may move stably relative to the first base 140.

Moreover, as shown in FIG. 8 and FIG. 9, the remote release module 100 further includes at least one first elastic member 150, the quantity of first elastic members 150 corresponds to the quantity of hooks 180. The first elastic member 150 is disposed between the first base 140 and the push-receiving portion 186 of the hook 180. When the button 110 is pressed, the third driving portion 134 drives the push-receiving portion 186 to move, causing the hook 180 to retract, the first elastic member 150 is compressed and stores elastic force. When the third driving portion 134 no longer pushes the push-receiving portion 186, the first elastic member 150 releases the elastic force and pushes the push-receiving portion 186 back to its original position, with the hook 180 protruding out of the first base 140.

In addition, as shown in FIG. 4, the remote release module 100 further includes a second base 160 fixed on the circuit board body 12 (FIG. 1), and the button 110 is pressably disposed on the second base 160. The second base 160 includes a first section 162 and a second section 164 connected in a bent manner, and the button 110 is pressably disposed on the first section 162. This design may position the button 110 farther away from the connector socket 14, making it more convenient for the user to press.

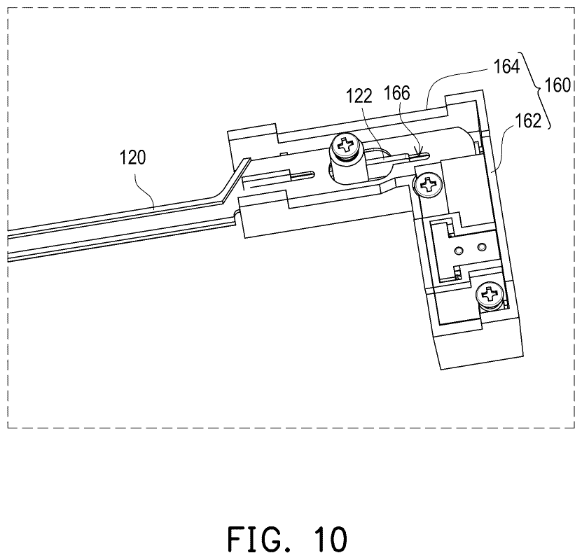

FIG. 10 is a schematic view of the bottom surface of the second base of the remote release module of FIG. 1. Please refer to FIG. 10. The second base 160 includes a third track 166 located on the second section 164, and the moving member 120 includes a protrusion 122, slidably disposed in the third track 166, so that the moving member 120 may move stably relative to the second base 160.

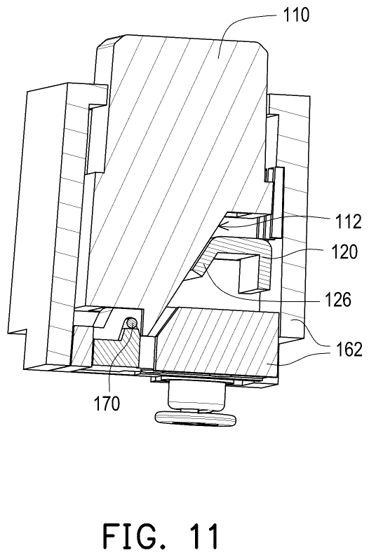

FIG. 11 is a cross-sectional view illustrating the button and the moving member of the remote release module of FIG. 1. Please refer to FIG. 11. In this embodiment, the button 110 includes a first inclined surface 112, and the moving member 120 includes a second inclined surface 126 leaned on the first inclined surface 112. When the button 110 is pressed downwardly, the first inclined surface 112 of the button 110 pushes the second inclined surface 126 of the moving member 120, causing the moving member 120 to move towards the right side of FIG. 11. The button 110 and the moving member 120 may change the direction of movement through the cooperation of the first inclined surface 112 and the second inclined surface 126.

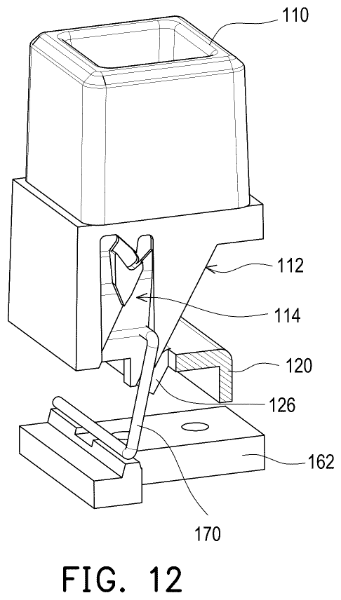

FIG. 12 is a schematic view illustrating the button, the second elastic member, and the local moving member of the remote release module of FIG. 1. Please refer to FIG. 12. In this embodiment, the button 110 is a push-push type button 110. When the button 110 is pressed, one end of a second elastic member 170 slides on a groove structure 114 on a wall surface of the button 110, so that the button 110 stays at a lower position (FIG. 3A) or an upper position (FIG. 2A). Therefore, in this embodiment, the user does not need to continuously press the button 110. By pressing once, the button 110 will stay at the lower position, keeping the hook 180 in a retracted state. After the user removes the expansion card 20 (FIG. 1), pressing the button 110 again will allow the hook 180 to return to its original position, which is quite convenient for use.

In summary, in the circuit board device and remote release module of the present invention, the button is linked with the moving member, with the second driving portion of the rotating shaft linked to the first driving portion. The at least one hook is disposed beside to at least one third driving portion of the rotating shaft. When the button is pressed, it drives the moving member, the first driving portion drives the second driving portion, causing the rotating shaft to rotate, which in turn causes at least one third driving portion to drive at least one hook to retract. Since the button may be disposed at a remote location without being shielded, it may drive the hook to retract from a remote position to complete the release of the expansion card. Moreover, the quantity of the third driving portion and the hook may be one or more, therefore, the button may simultaneously drive one or more hooks, thus enhancing convenience.

What is claimed is:

1. A remote release module, comprising:
a button;
a moving member, linked with the button, and comprising a first driving portion;
a rotating shaft, comprising a second driving portion and at least one third driving portion protruding from a peripheral side, the second driving portion linked with the first driving portion; and
at least one hook, disposed beside the at least one third driving portion, wherein
when pressing the button, the moving member is driven, the first driving portion drives the second driving portion, causing the rotating shaft to rotate, thereby causing the at least one third driving portion to drive the at least one hook to retract.

2. The remote release module as claimed in claim 1, further comprising a first base, wherein the rotating shaft is pivotally disposed at the first base, the first base comprises at least one first track, the at least one hook moves along the at least one first track.

3. The remote release module as claimed in claim 2, wherein the first base comprises at least one second track, in communication with the at least one first track, the at least one hook moves along the at least one second track.

4. The remote release module as claimed in claim 2, further comprising at least one first elastic member, disposed between the first base and the at least one hook.

5. The remote release module as claimed in claim 1, wherein the rotating shaft comprises an end surface and a blocking portion protruding from the peripheral side, a projection of the blocking portion projected onto the end surface is located between a projection of the second driving portion projected onto the end surface and a projection of the at least one third driving portion projected onto the end surface.

6. The remote release module as claimed in claim 1, wherein the at least one third driving portion comprises a plurality of third driving portions, the third driving portions extend in parallel from the peripheral side, the at least one hook comprises a plurality of hooks, the hooks are respectively disposed beside the third driving portions, when pressing the button, the moving member is driven, the first driving portion drives the second driving portion, causing the rotating shaft to rotate, thereby causing the third driving portions to drive the hooks to retract simultaneously.

7. The remote release module as claimed in claim 1, further comprising a second base, wherein the button is pressably disposed at the second base, the second base comprises a third track, the moving member comprises a protrusion, slidably disposed in the third track.

8. The remote release module as claimed in claim 7, wherein the second base comprises a first section and a second section connected in a bent manner, the button is pressably disposed at the first section, the third track is located at the second section.

9. The remote release module as claimed in claim 1, wherein the button comprises a first inclined surface, the moving member comprises a second inclined surface leaned on the first inclined surface.

10. The remote release module as claimed in claim 1, wherein the button is a push-push button, when pressing the button, one end of a second elastic member slides along a groove structure on a wall surface of the button, so that the button stays at a lower position or an upper position.

11. A circuit board device, comprising:
a circuit board body;
at least one connector socket, disposed on the circuit board body; and
a remote release module as claimed in claim 1, wherein the at least one hook is driven by the button, so as to retract away from the at least one connector socket.

12. The circuit board device as claimed in claim 11, wherein the remote release module further comprises a first base, the rotating shaft is pivotally disposed at the first base, the first base comprises at least one first track, the at least one hook moves along the at least one first track.

13. The circuit board device as claimed in claim 12, wherein the first base comprises at least one second track, in communication with the at least one first track, the at least one hook moves along the at least one second track.

14. The circuit board device as claimed in claim 12, wherein the remote release module further comprises at least one first elastic member, disposed between the first base and the at least one hook.

15. The circuit board device as claimed in claim 11, wherein the rotating shaft comprises an end surface and a blocking portion protruding from the peripheral side, a projection of the blocking portion projected onto the end surface is located between a projection of the second driving portion projected onto the end surface and a projection of the at least one third driving portion projected onto the end surface.

16. The circuit board device as claimed in claim 11, wherein the at least one third driving portion comprises a plurality of third driving portions, the third driving portions extend in parallel from the peripheral side, the at least one hook comprises a plurality of hooks, the hooks are respectively disposed beside the third driving portions, when pressing the button, the moving member is driven, the first driving portion drives the second driving portion, causing the rotating shaft to rotate, thereby causing the third driving portions to drive the hooks to retract simultaneously.

17. The circuit board device as claimed in claim 11, wherein the remote release module further comprises a second base, wherein the button is pressably disposed at the second base, the second base comprises a third track, the moving member comprises a protrusion, slidably disposed in the third track.

18. The circuit board device as claimed in claim 17, wherein the second base comprises a first section and a second section connected in a bent manner, the button is pressably disposed at the first section, the third track is located at the second section.

19. The circuit board device as claimed in claim 11, wherein the button comprises a first inclined surface, the moving member comprises a second inclined surface leaned on the first inclined surface.

20. The circuit board device as claimed in claim 11, wherein the button is a push-push button, when pressing the button, one end of a second elastic member slides along a groove structure on a wall surface of the button, so that the button stays at a lower position or an upper position.
